(19) United States
(12) Patent Application Publication
(10) Pub. No.: US 2005/0242439 A1
(43) Pub. Date: Nov. 3, 2005

(54) METHOD AND STRUCTURE FOR CONNECTING GROUND/POWER NETWORKS TO PREVENT CHARGE DAMAGE IN SILICON ON INSULATOR

(75) Inventors: Kenneth L. DeVries, Hopewell Junction, NY (US); Jeffrey P. Gambino, Westford, VT (US); Stephen E. Luce, Underhill, VT (US); James D, Warnock, Somers, NY (US); Francis R. White, Essex, VT (US)

Correspondence Address: MCGINN & GIBB, PLLC, 8321 OLD COURTHOUSE ROAD, SUITE 200, VIENNA, VA, 22182-3817, US

(73) Assignee: INTERNATIONAL BUSINESS MACHINES CORPORATION, Armonk, NY (US)

(21) Appl. No.: 10/709,325

(22) Filed: Apr. 28, 2004

(51) Int. Cl. H01L 23/48

(52) U.S. Cl. 257/758

(57) ABSTRACT

A structure (and method) for an electronic chip, includes a first circuit design module having a first grid and a second circuit design module having a second grid. The first grid and the second grid are interconnected in a fabrication layer no later than a first metallization layer that accumulates a charge during a plasma process in the fabrication.

### BACKGROUND OF INVENTION

1. Field of the Invention

The present invention generally relates to a method (and structure) for fabricating circuits using silicon on insulator (SOI) technology, and, more specifically, to a method (and structure) in which grids of separately-designed circuit modules are interconnected at a fabrication stage so that differential charging is precluded during plasma processing after metal layers have been added.

2. Description of the Related Art

Charge damage from plasma processes can degrade yield and reliability of integrated circuits. It is known that, for devices fabricated on bulk silicon (Si), a charge differential can develop between a gate electrode and a substrate, resulting in large current flow through a gate dielectric, and hence damage to the gate dielectric.

FIG. 1 shows the mechanism 100 of this breakdown process in bulk Si in more detail. Transistor 101 has a gate 102 and drain diffusion region 103 and source diffusion region 104. The gate 102 is interconnected to various other points in the circuit by way of metal interconnect 105. The drain diffusion region 103 is likewise interconnected to other points in the circuit through metal interconnect 106. Although the source diffusion 104 might be likewise interconnected to other points in the circuit, this interconnection is not shown in FIG. 1, since its effects are similar to that of the drain.

When a plasma process 107 is executed on the wafer containing transistor 101, there will be charges that build up on the wiring 105, 106 for the interconnects to the gate 102 and drain 103.

However, because bulk silicon will allow the drain diffusion region 103 to dissipate the charge (reference label 108) on interconnect wiring 106, plasma processing causes a differential charge across the gate oxide 109 of transistor 101.

As a result, gates in bulk Si devices are often connected to protect diodes (not shown in FIG. 1), that equalize charge between the gate 102 and substrate 110 during plasma processing, thereby protecting the gate dielectric 109 from plasma damage.

In contrast to bulk silicon devices, for devices fabricated on silicon on insulator (SOI) substrates, the device silicon (Si) layer is generally isolated from the substrate. Therefore, using the above mechanism for bulk silicon as a model, conventional wisdom teaches that differential charges will not occur during plasma processing for SOI devices.

However, recently it has been observed by the inventors that charge damage can occur in SOI if the gate charges to a different potential than the source/drain (S/D) diffusions. That is, the present inventors have observed that, under certain conditions, such differential charging can indeed occur if the gate and S/D diffusions are connected to different power or ground networks. This results in damage to the gate dielectric, and reduces yield.

At present, there is no method to protect devices on SOI from differential charging when gates and diffusions are connected to different power or ground grids.

### SUMMARY OF INVENTION

Therefore, in view of the exemplary foregoing, and other, problems, drawbacks, and disadvantages of the conventional systems, it is an exemplary purpose of the present invention to provide a structure and method for solving a problem in which differential charges build up in SOI chips in plasma process steps during fabrication.

It is another exemplary purpose of the present invention to provide a method of improving manufacturing yield of electronic chips in which a chip circuit is divided into separately-designed modules and at least one of the design modules includes a grid to be interconnected to a corresponding grid in another design module, and the size of the grid allows a significant differential charge to build up during plasma processing stages of the fabrication of the chip.

It is another exemplary purpose of the present invention to improve manufacturing yield by providing a solution to potential damage caused by plasma process differential charging in a more generic environment in which a component structural layer is activated during plasma processing and charges due to the plasma process are allowed to selectively dissipate from interconnect wiring having considerable aggregate surface area relative to the surface area of design modules of an electronic chip.

To achieve these and other exemplary purposes and aspects, in an exemplary first aspect of the present invention, described herein is an electronic chip, including a first circuit design module having a first grid and a second circuit design module having a second grid. The first grid and the second are interconnected in a fabrication layer no later than a first metallization layer that accumulates a charge during a plasma process in the fabrication.

In an exemplary second aspect of the present invention, described herein is a method of at least one of designing an electronic chip and fabricating the electronic chip, including, for an electronic circuit on the electronic chip, the electronic circuit having been segmented into a plurality of design modules, wherein at least one of the design modules has at least one grid to be interconnected to a corresponding grid in a second of the design modules, interconnecting the at least one grid to the corresponding grid in a stage of fabrication of the chip such that a plasma processing of the fabrication does not cause a differential charge that damages a component of the chip.

In an exemplary third aspect of the present invention, described herein is an electronic apparatus including at least one electronic chip, wherein the at least one chip includes a first circuit design module having a first grid and a second circuit design module having a second grid, and wherein the first grid and the second grid are interconnected in a fabrication layer no later than a first metallization layer that accumulates a charge during a plasma process in the fabrication.

Thus, the present invention provides a solution to a problem of differential charging during a plasma process for SOI devices, in which conventional wisdom considers such problem should not be present, since the layer containing electronic components is isolated from the substrate.

### BRIEF DESCRIPTION OF DRAWINGS

The foregoing and other exemplary purposes, aspects and advantages will be better understood from the following detailed description of an exemplary embodiment of the invention with reference to the drawings, in which:

FIG. 1 shows a conventional bulk silicon device and the mechanism 100 for plasma process differential charging damage in bulk silicon;

FIG. 2 exemplarily illustrates the problem 200 of plasma process differential charging damage in SOI devices;

FIG. 3 exemplarily illustrates that sections of a chip design 300 are designed piecemeal by engineering teams so that the various separately-designed circuit sections are interconnected in the final metal layers;

FIG. 4 exemplarily illustrates a conventional design method 400 in which grids are isolated at lower metal levels;

FIG. 5 exemplarily illustrates an embodiment 500 of the present invention in which grids from different design modules are interconnected by diffusion regions;

FIG. 6 exemplarily illustrates an embodiment 600 of the present invention in which grids from different design modules are interconnected by FET gates;

FIG. 7 exemplarily illustrates an embodiment 700 of the present invention in which grids from different design modules are interconnected by the source and drain of an FET transistor;

FIG. 8 exemplarily illustrates an embodiment 800 of the present invention in which grids from different design modules are interconnected by a local interconnect; and

FIG. 9 exemplarily illustrates an embodiment 900 of the present invention in which grids from different design modules are interconnected by designing a metallization layer to electrically connect at the boundary of the design modules.

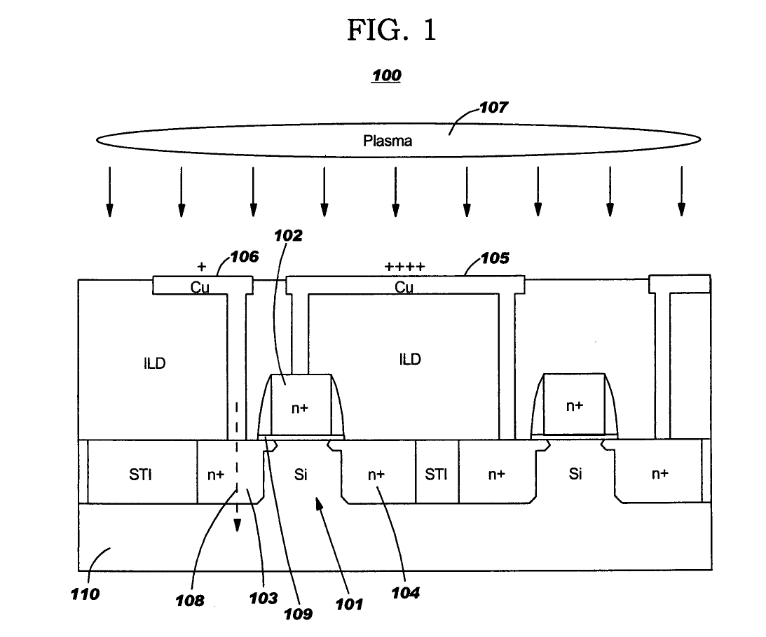

### DETAILED DESCRIPTION

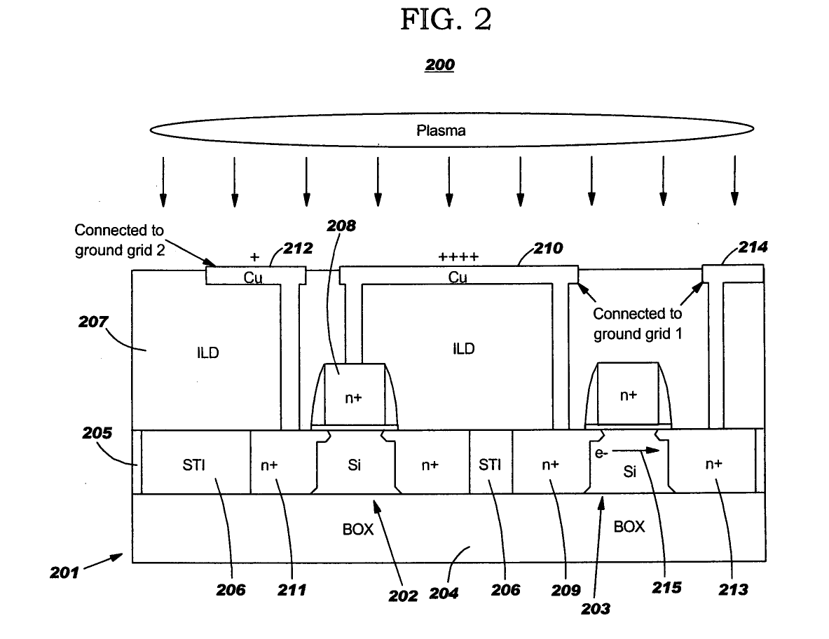

Referring now to the drawings, and more particularly to FIGS. 2-9, exemplary embodiments that teach exemplary aspects of the present invention will now be described.

FIG. 2 exemplarily shows a plasma process 200 for an SOI wafer 201 containing two transistors 202, 203. It is noted that a buried oxide (BOX) layer 204 serves to isolate a silicon layer 205, wherein the two transistors 202, 203 have been formed, from the underlying wafer (not shown), thereby providing the basic SOI structure, and that the two transistors 202, 203 are isolated on the silicon layer 205 by shallow trench isolation (STI) regions 206, as is well known in the art.

In FIG. 2, transistors 202, 203 are covered by and inter level dielectric layer (ILD) 207 and a gate 208 of transistor 202 interconnects to a drain 209 of transistor 203 via metal interconnect 210. It is noted that a drain 211 of transistor 202 interconnects to other points in the circuit by way of metal interconnect 212, and that a source 213 of transistor of transistor 203 interconnects to other points of the circuit by way of metal interconnect 214.

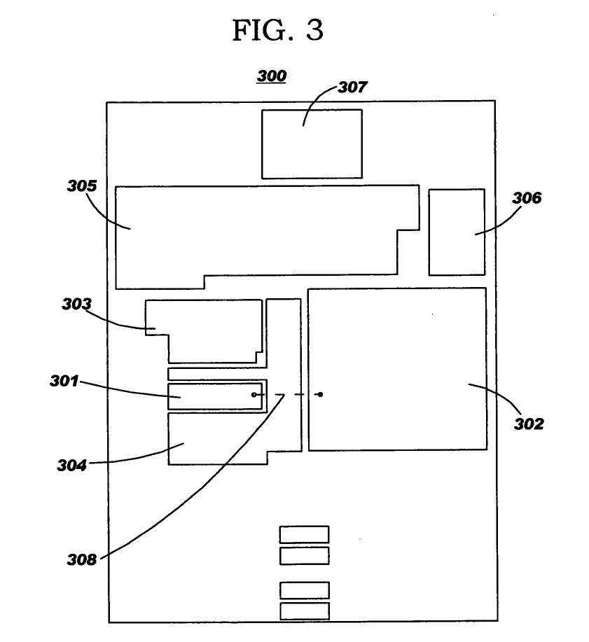

To further explain the problem solved by the present invention, FIG. 3 exemplarily shows that integrated circuits are customarily designed by different engineering teams, such that different design teams will be working simultaneously on different portions of the circuit. That is, chip 300 is actually the design effort of various design teams, such that different design modules or sections 301-307 will be designed by different teams of engineers. In this design effort, it would be common that a transistor gate in section 301 will interconnect with a point in another section 302, as exemplarily shown by the dashed line 308.

Thus, returning to FIG. 2, it is assumed that transistor 202 is located in design portion 301 and that the gate 208 of transistor 202 interconnects to a different design portion 302. The present inventors have observed that the plasma charging problem occurs most likely when there is a relatively large amount of wiring interconnect to the damaged transistor 202.

That is, damage is more likely in a scenario such as illustrated in FIG. 3, in which a transistor gate 208 interconnects to a relatively large number of points in a circuit, such as to a ground grid, in an adjacent circuit design portion 302, the transistor 202 is located in adjacent circuit design portion 301, and the source/drain of transistor 202 likewise interconnects to a relatively large number of points in design portion 301, such as a ground grid or power line.

Thus, for the purpose of discussion, it is assumed that the metal interconnect 212 for drain 211 is either a ground grid 1 or power grid 1 (shown in FIG. 2) in one design portion (e.g., 301 in FIG. 3) and the transistor 202 gate 208 interconnects to the ground grid 2 or power grid 2 in another design portion (e.g., 302 in FIG. 3). Therefore, metal layers 210 and 214 represent a ground grid 2 or power grid 2 in a circuit portion designed by another team.

In view of the solution offered by the present invention, the present inventors surmise that the reason for the observed failures of SOI devices is because of this piecemeal design effort, in combination with surmising that:
the plasma process 200 shown in FIG. 2 inherently has lateral differences in its charging of components on the chip, such that differences in charging inherently occur during the plasma process. Therefore, the charging on metal layers 210, 212, and 214 will differ because of different metal surface area and the lateral differences in the charging from the plasma processing; and
the silicon layer 205 in FIG. 2 is activated during the plasma processing to be conductive such that charges migrate during the plasma processing. That is, returning to FIG. 2, the present inventors surmise that the ultraviolet light (UV) present during the plasma processing causes the silicon layer 205 to be conductive to charges during plasma processing, as shown by label 215 in FIG. 2.

The problem of the observed breakdown of gates in the SOI environment, contrary to the conventional wisdom, can now be explained in view of FIG. 3, wherein has been illustrated that sections of the chip design are typically designed piecemeal by different engineering teams. The conventional practice in SOI circuit design is to interconnect the various separately-designed circuit sections 301-307 in the final metallization layers, such as M5 or greater.

The present inventors consider that the gate metal interconnections to other sections of the piecemeal design are subject to overvoltage breakdown during plasma processing, perhaps because of lateral differences in the charging effects on the various wiring levels of the various piecemeal sections of the chip design.

To overcome this problem, the present invention teaches that the gate breakdown observed in SOI chips can be avoided by interconnecting separately-designed sections of the circuit in an earlier step of metallization (e.g., earlier than M5, and preferably at M1, and even more preferably before M1), rather than the conventional practice of interconnecting design sections at the final metallization layers (e.g., M5).

That is, in the conventional design process, power and ground networks for different macros within a large integrated circuit are generally not connected until the upper wiring layers because of hierarchical design practices.

However, as explained above, this results in the possibility of differential charging across the gate dielectric during plasma processing at the lower wiring layers (e.g., for layers where the ground/power grids of different macros are still isolated from each other).

To minimize the risk of differential charging of the power/ground grids, the present invention teaches connecting all the power grids in different macros and all of the ground grids at the earliest possible process step (e.g., at metallizationM1 or earlier). By doing this, the risk of differential charging between the gate and diffusion (due to differences in charging of the different power/ground grids) is minimized. Thus, in FIG. 2 for example, the ground grid metal 212 of ground grid 2 in FIG. 2 would be interconnected at an early fabrication stage to the ground grid 1 metal 210, 214. As previously mentioned, these grids would be interconnected in the conventional method at one of the final metallization steps when the design modules are routinely interconnected.

This minimizing of differential charging of the present invention can be done in various ways, as described below.

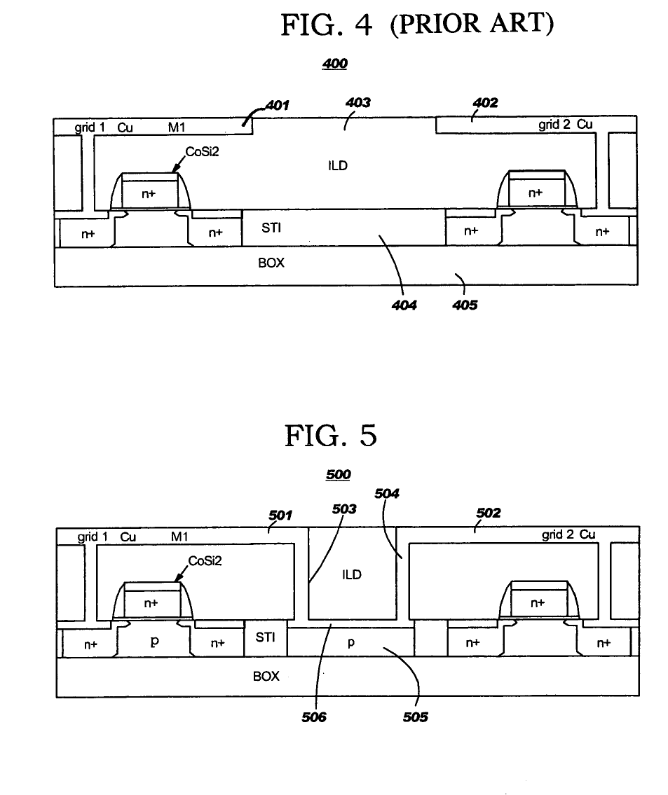

As shown in FIG. 4, in contrast to the present invention, the conventional method 400 of SOI design is to keep ground grids 401, 402 isolated at the lower metal layers, to be interconnected at a later metallization level. Specifically, grids 401, 402 are exemplarily isolated by the ILD 403, STI 404, and BOX 405.

### First Exemplary Embodiment

In contrast to FIG. 4, FIGS. 5-9 show various exemplary methods in which the various circuit sections can be interconnected at earlier fabrication stages, thereby precluding the potential that ground grids, power grids, or any other grid that occupies a relatively large area, will be subject to differential charging during plasma processes. It should be noted that these methods are presented only as being exemplary, and that any other method, consistent with the intent of the present invention to interconnect grids of different design modules at an early stage of fabrication, as discussed herein, is intended as being covered by the present invention.

Thus, as shown in a first exemplary embodiment 500 in FIG. 5, grids 501, 502 from two different design modules can be interconnected by a diffusion region 505. More specifically, vias 503, 504 interconnect the grids 501, 502 via the diffusion region 505, as exemplarily covered in this figure by a silicide layer 506 (e.g., such as cobalt silicide or titanium silicide).

It should be readily recognized by one of skill in the art, after taking the present specification as a whole, that the vias 503, 504 can be of any material that is conductive. Conventional vias are implemented using copper or aluminum, but any conductive material, such as other metals or amorphous silicon, could also be used.

It should also be readily recognized by one of skill in the art, after taking FIGS. 5-9 as a whole, that the interconnection can be by any method in which conduction can occur during the plasma process, including some methods, such as shown later in FIG. 7, in which the interconnect would not normally be conductive but for the ultraviolet rays of the plasma process.

### Other Exemplary Embodiments

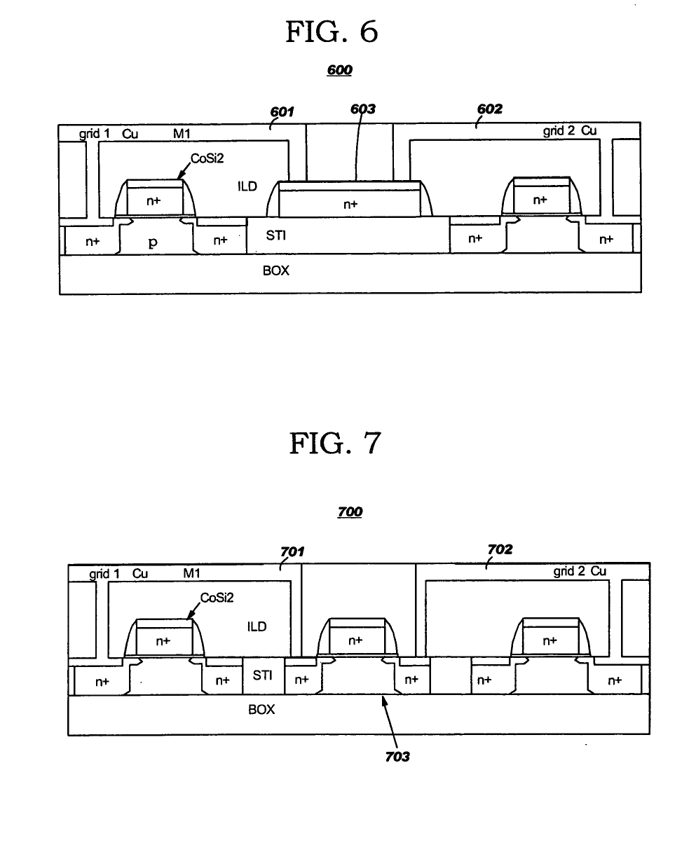

FIG. 6 shows a second exemplary embodiment 600 in which grids 601, 602 are interconnected by a gate structure 603. It is noted that the gate structure need not be a part of an actual transistor, but could be an isolated gate conductor without a transistor, as the structure 603 in FIG. 6 illustrates.

FIG. 7 shows an exemplary embodiment 700 in which grids 701, 702 are interconnected by FET 703, keeping in mind that the silicon layer containing the FET 703 is considered as being conductive during the plasma processing.

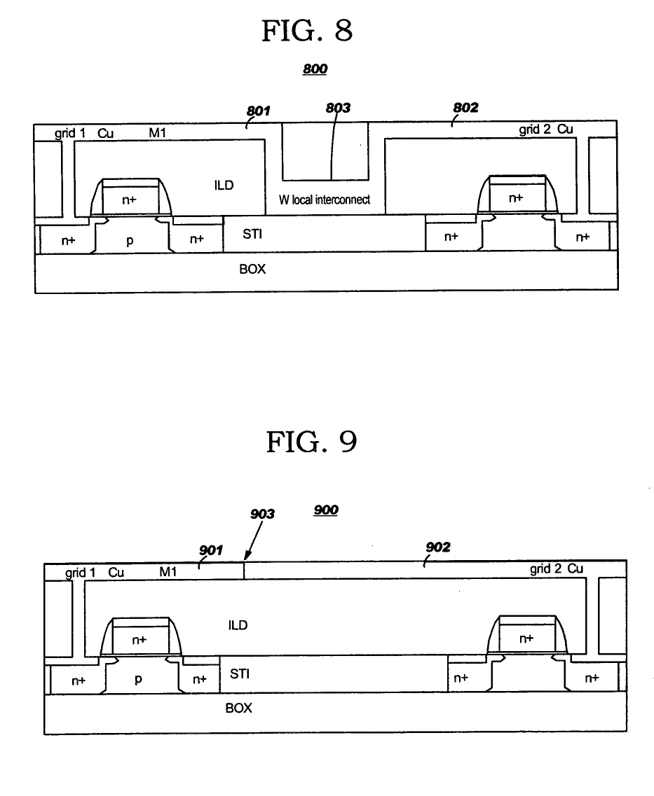

FIG. 8 shows an exemplary embodiment 800 in which grids 801, 802 are interconnected by a local interconnect 803 at a lower level. This local interconnect 803 can be made of any conductive material. What should be considered as significant is that the local interconnect is fabricated at a fabrication level prior to having the grids 801, 802 exposed to a plasma processing stage.

FIG. 9 shows an exemplary embodiment 900 in which the grids 901, 902 are interconnected by a metal layer that is designed to match up at the boundary 903 of the two design sections at an early metallization stage.

All of the above methods of interconnecting grids from different sections share a feature that the grid interconnection is done at a stage prior to having metal layers of the various design sections subjected to plasma processing. Thus, it is not important which technique is used for interconnecting the grids, and the specific technique of interconnecting the two grids can depend upon the specific chip circuit.

Rather, the present invention should be considered as teaching that the grids of the various design modules of a chip be appropriately interconnected by a conductive mechanism at an early stage. Preferably, by “early stage”, the present invention means a stage prior to a fabrication step in which the grids are subjected to plasma processing which, in conventional design and fabrication techniques, are isolated grids during the plasma processing step.

Therefore, in the present invention, typically, although not necessarily, metal grids, such as ground grids and power supply lines which will ultimately be interconnected in conventional design approaches, as a common ground grid across the various design modules or as a common power supply lines across the design modules, are interconnected at early stages of the fabrication process.

It will also be readily recognized by one of ordinary skill in the art, after considering the discussion above as a whole, that the techniques discussed herein can be generalized to extend beyond SOI gate breakdown protection.

That is, more generally, the present invention is intended as providing a solution to plasma processing breakdown problems in any environment in which there is no leakage of carriers to the substrate, or low leakage of carriers to the substrate, and there are relatively large metal grids upon which charges accumulate during plasma processing.

By early interconnection of these relatively large metal grids, conventionally interconnected as design modules are interconnected at higher levels of metallization, large charge differentials cannot build up between grid sections during plasma processing. Grids that are most commonly sufficiently large to be of concern would be ground grids and power grids, but any metallization layer having a relatively large surface area because of the large number of points interconnected might be of concern.

It is also pointed out, for clarity, that the present invention does not intend that power grids and ground grids be interconnected, even temporarily. Rather, what is being interconnected is, for example, ground grid 1 in design module 1 to ground grid 2 in design module 2, or power grid 1 in design module 1 to power grid 2 in design module 2.

Finally, it is also pointed out that the grids that seem to cause the charging problems during plasma processing are grids that are relatively large within the design modules. Thus, not every grid (e.g., wherein grid is meant as referring to an interconnection between a number of points in the design module) needs to be protected in the manner presented by the present invention.

The present inventors have discovered that “relatively large” might exemplarily mean an area of the metal that is connected to the gate electrode of a transistor. In practice, it has been observed that charge damage occurs when the total metal area connected to the gate is greater than 1E6 μm². It is noted that metal area is calculated assuming that Si is a conductor during the plasma process, so that, in FIG. 2, metal areas connected to gate 208 would include metal layer 214.

It is possible that, with thinner gate dielectrics, a metal area as low as 1E3 μm² could cause damage, so that “relatively large” depends upon parameters such as the ability of dielectrics, such as gate dielectric material, to withstand voltage breakdown.

While the invention has been described in terms of exemplary embodiments, those skilled in the art will recognize that the invention can be practiced with modification within the spirit and scope of the appended claims.

Further, it is noted that, Applicant's intent is to encompass equivalents of all claim elements, even if amended later during prosecution.

1. An electronic chip, comprising:
a first circuit design module having a first grid; and
a second circuit design module having a second grid, wherein said first grid and said second grid are interconnected in a fabrication layer no later than a first metallization layer of said chip that accumulates a charge during a plasma process in said fabrication.

2. The electronic chip of claim 1, wherein at least one of said first grid and said second grid comprises a metallization grid.

3. The electronic chip of claim 1, wherein said first grid and said second grid comprise one of a power grid and a ground grid.

4. The electronic chip of claim 1, wherein said first grid and said second grid are interconnected by at least one of:
a diffusion region;
a gate of a field effect transistor;
a source of a field effect transistor connected to said first grid and a drain of said field effect transistor connected to said second grid;
a local interconnect; and
a first metallization layer that is designed to electrically interconnect at a boundary of said first circuit design module and said second circuit design module.

5. The electronic chip of claim 1, wherein an interconnect between first grid and said second grid is conductive during said plasma processing and is nonconductive during an operation of said chip unless activated by a signal.

6. The electronic chip of claim 1, wherein said chip comprises components fabricated in a layer that has substantially no leakage of carriers to a substrate of said chip.

7. The electronic chip of claim 6, wherein said chip includes a silicon on insulator (SOI) structure.

8. The electronic chip of claim of claim 6, wherein said layer is temporarily activated by said plasma processing such that carriers in said layer are migratable during said plasma processing.

9. The electronic chip of claim 2, wherein at least one of said first grid and said second grid comprises a metal grid that includes a predetermined surface area of at least one of said first circuit design module and said second circuit design module.

10. An electronic apparatus comprising:
an electronic chip fabricated in accordance with claim 1.

11. A method of at least one of designing an electronic chip and fabricating said electronic chip, said method comprising:
interconnecting at least one grid of a design module of an electronic circuit formed on said chip with a corresponding grid in a second design module in a stage of fabrication of said chip such that a plasma processing of said fabrication does not cause a differential charge that damages a component of said chip.

12. The method of claim 11, wherein at least one of first grid and said second grid each comprise a grid formed by metalization.

13. The method of claim 11, wherein said first grid and said second grid comprise one of a power grid and a ground grid.

14. The method of claim 11, wherein said first grid and said second grid are interconnected by at least one of:
a diffusion region;
a gate of a field effect transistor;
a source of a field effect transistor connected to said first grid and a drain of said field effect transistor connected to said second grid;
a local interconnect; and
a first metallization layer that is designed to electrically interconnect at a boundary of said first circuit design module and said second circuit design module.

15. The method of claim 11, wherein said chip comprises components fabricated in a layer that has substantially no leakage of carriers to a substrate of said chip.

16. The method of claim 15, wherein said chip comprises a silicon on insulator (SOI) structure.

17. The method of claim of claim 11, wherein said layer is temporarily activated by said plasma processing such that carriers in said layer are migratable during said plasma processing.

18. The method of claim 12, wherein at least one of said first grid and said second grid comprises a metal grid that is a predetermined surface area of at least one of said first circuit design module and said second circuit design module.

19. An electronic apparatus comprising:
at least one electronic chip, comprising:
a first circuit design module having a first grid;
a second circuit design module having a second grid; and
means for electrically interconnecting said first grid and said second grid no later than a first metallization layer that accumulates a charge during a plasma process in a fabrication of said chip.

20. The electronic apparatus of claim 19, wherein at least one of said at least one electronic chip comprises a chip including a silicon on insulator (SOI) structure.
